(19) United States
(12) Patent Application Publication
(10) Pub. No.: US 2024/0283212 A1
(43) Pub. Date: Aug. 22, 2024

(54) METHOD FOR MANUFACTURING SEMICONDUCTOR LASER DEVICE, AND SEMICONDUCTOR LASER DEVICE

(71) Applicant: HAMAMATSU PHOTONICS K.K., Hamamatsu-shi (JP)

(72) Inventors: Keita FURUOKA, Hamamatsu-shi (JP); Atsushi SUGIYAMA, Hamamatsu-shi (JP); Takehito NAGAKURA, Hamamatsu-shi (JP); Satoru OKAWARA, Hamamatsu-shi (JP)

(73) Assignee: HAMAMATSU PHOTONICS K.K., Hamamatsu-shi (JP)

(21) Appl. No.: 18/438,567

(22) Filed: Feb. 12, 2024

(30) Foreign Application Priority Data
Feb. 16, 2023 (JP) 2023-022490

(51) Int. Cl. H01S 5/02

(52) U.S. Cl. CPC H01S 5/0203; H01S 5/0206

(57) ABSTRACT

A method for manufacturing a semiconductor laser device of an embodiment includes a first step of preparing a wafer and a second step of forming a device dividing groove by etching along a device dividing line. The device dividing groove has a first portion and a second portion. At least a portion of an inner surface of the device dividing groove formed by the first portion is inclined with a Z-axis direction such that a width of the device dividing groove in a Y-axis direction decreases from a first primary surface side toward a second primary surface side. An inclination angle of an inner surface of the first portion with respect to the Z-axis direction is larger than an inclination angle of an inner surface of the second portion with respect to the Z-axis direction.

### TECHNICAL FIELD

The present disclosure relates to a method for manufacturing a semiconductor laser device and a semiconductor laser device.

### REFERENCE TO RELATED APPLICATIONS

This application claims the benefit of priority from Japanese Patent Application No. 2023-22490 filed on Feb. 16, 2023, the entire contents of which are incorporated herein by reference.

### BACKGROUND

As a method for manufacturing a semiconductor laser device, a method for dividing a laser bar into a plurality of semiconductor laser devices by forming device separation grooves (recesses) and breaking the semiconductor laser device along the device separation grooves has been known (for example, Japanese Unexamined Patent Publication No. 2011-29261). In the method disclosed in Japanese Unexamined Patent Publication No. 2011-29261, recesses (vertical grooves) extending perpendicularly to a wafer front surface with an equal width are formed as the device separation grooves.

### SUMMARY

In the method for manufacturing a semiconductor laser device as described above, it is necessary to accurately perform device division in a short time, but the method disclosed in Japanese Unexamined Patent Publication No. 2011-29261 has room for improvement from the above viewpoint.

Therefore, an object of one aspect of the present disclosure is to provide a method for manufacturing a semiconductor laser device and a semiconductor laser device capable of shortening a time required for device division and improving accuracy of device division.

The present disclosure includes a method for manufacturing a semiconductor laser device of [1] to [12] to be below, and a semiconductor laser device of [13].

[1] There is provided a method for manufacturing a semiconductor laser device that includes a semiconductor substrate and a semiconductor stacked body including an active layer and stacked on the semiconductor substrate.

The method includes
a first step of preparing a semiconductor member that includes a plurality of device portions to each become the semiconductor laser device, and includes a substrate layer including the semiconductor substrate of each of the plurality of device portions and a semiconductor layer including the semiconductor stacked body of each of the plurality of device portions, in the semiconductor member, the plurality of device portions being arrayed at least in a second direction perpendicular to a first direction parallel to an optical waveguide direction of the semiconductor stacked body as viewed from a thickness direction of the semiconductor member, and
a second step of forming a device dividing groove by etching on a first primary surface on a side of the semiconductor member on which the semiconductor layer is positioned with respect to the substrate layer along a device dividing line extending in the first direction to partition the plurality of device portions arrayed in the second direction.

The device dividing groove has a first portion positioned on an opening side of the device dividing groove and a second portion positioned on a bottom portion side of the device dividing groove with respect to the first portion,
at least a portion of a first inner surface of the device dividing groove formed by the first portion in the second direction is inclined with the thickness direction such that a width of the device dividing groove in the second direction decreases from the first primary surface side toward a second primary surface side opposite to the first primary surface in the semiconductor member, and
an inclination angle of the first inner surface of the first portion with respect to the thickness direction is larger than an inclination angle of the first inner surface of the second portion with respect to the thickness direction.

According to the manufacturing method of the above [1], the first inner surface of the first portion of the device dividing groove is inclined with respect to the thickness direction, and thus, the semiconductor member can be easily divided along the device dividing line. On the other hand, in a case where the entire inner surface of the device dividing groove is inclined at a substantially constant inclination angle with respect to the thickness direction, it is difficult to accurately align the central position of the bottom portion of the device dividing groove on the device dividing line, and there is a concern that device division is not accurately performed along the device dividing line. Therefore, as described above, the second portion having a gentler inclination is provided on the first portion on the bottom portion side of the device dividing groove, and thus, the central position of the bottom portion of the device dividing groove can be accurately aligned on the device dividing line. Accordingly, according to the above configuration, a time required for device division can be shortened by facilitating device division by the first portion, and the accuracy of device division can be improved by accurately controlling the device division position by the second portion.

[2] In the method for manufacturing a semiconductor laser device of [1], the device dividing groove penetrates the semiconductor layer, and reaches the substrate layer.

According to the above [2], since only the substrate layer may be divided in order to perform device division, it is possible to reduce a risk of occurrence of cracks inside the semiconductor layer at the time of device division or peeling of the semiconductor layer from the substrate layer.

[3] In the method for manufacturing a semiconductor laser device of [2], an inner surface of the first portion of the device dividing groove constitutes a side surface of a mesa light emitting portion of each of the plurality of device portions, and
the first portion penetrates the semiconductor layer, and reaches the substrate layer.

According to the above [3], since the side surface of the mesa light emitting portion is formed as the inclined surface inclined with respect to the thickness direction, it is possible to suitably suppress oscillation of the mesa light emitting portion in a lateral direction (oscillation in the second direction).

[4] In the method for manufacturing a semiconductor laser device of any one of [1] to [3], a bottom portion of the device dividing groove has a bottom surface extending in the second direction.

The device dividing groove having the bottom surface is formed as in the above [4], and thus, the mechanical strength of the semiconductor member can be increased as compared with a case where the device dividing groove is formed in the V shape. As a result, for example, in a case where the back surface processing or the like is performed on the semiconductor member after the device dividing groove is formed, it is possible to suppress the damage to the semiconductor member and to improve the yield. In addition, since the accuracy of etching deteriorates as the inclination increases, in a case where the device dividing groove is formed in a V shape (that is, in a case where the entire inner surface of the device dividing groove is formed as the inclined surface), it is difficult to control the shape of the device dividing groove formed by etching, and as a result, there is a concern that the dividing direction (a direction along the dividing surface) at the time of device division becomes unstable. On the other hand, etching is performed such that the device dividing groove has the bottom surface, and thus, the shape of the device dividing groove can be more accurately controlled than in a case where the device dividing groove is formed in the V shape. As a result, the accuracy of device division can be improved.

[5] In the method for manufacturing a semiconductor laser device of [4], a width of the bottom surface of the device dividing groove in the second direction is 20 μm or less.

According to the above [5], the width of the bottom surface is suppressed to a certain value or less (20 μm or less), and thus, it is possible to easily divide the device along the device dividing groove while obtaining the effect of the case where the device dividing groove has the bottom surface as described above.

[6] In the method for manufacturing a semiconductor laser device of any one of [1] to [5], the etching is dry etching using a chlorine-based gas.

According to the above [6], since it is possible to easily and accurately perform vertical etching, it is possible to accurately control the shape of the device dividing groove.

[7] In the method for manufacturing a semiconductor laser device of any one of [1] to [6], a second inner surface of the device dividing groove in the first direction is inclined with respect to the second direction to become narrow toward a substantially central portion of the device dividing groove in the second direction toward an outside in the first direction.

According to the above [7], it is possible to facilitate the device division along the substantially central portion of the device dividing groove in the second direction as compared with a case where the shape of the device dividing groove as viewed from the thickness direction is a rectangular shape.

[8] In the method for manufacturing a semiconductor laser device of [7], the second inner surface of the device dividing groove is formed in an R shape as viewed from the thickness direction.

According to the above [8], the effect of the above [7] can be obtained, and the risk of occurrence of cracks in the second inner surface can be reduced by forming the second inner surface in the R shape as compared with a case where the second inner surface is formed in the angular shape.

[9] In the method for manufacturing a semiconductor laser device of any one of [1] to [8], an extending direction of the device dividing line is parallel to a [01-1] direction of the substrate layer.

According to the above [9], the device dividing lines are aligned with the [01-1] direction of the substrate layer which is the crystal orientation in which cracking is difficult, and thus, the mechanical strength of the semiconductor member after the device dividing grooves are formed can be suitably secured. As a result, in a case where the above-described back surface processing or the like is performed before device division, it is possible to suitably suppress damage to the semiconductor member.

In the method for manufacturing a semiconductor laser device of any one of [1] to [9], the plurality of device portions are arrayed in a matrix in the first direction and the second direction, and
the method further includes
a third step of forming a cleavage introducing groove to become a starting point of a cleavage on the first primary surface at a position overlapping a cleavage line extending in the second direction to partition the plurality of device portions arrayed in the first direction after the second step,
a fourth step of obtaining a plurality of laser bars including a plurality of device portions arrayed one-dimensionally in the second direction by cleaving the semiconductor member along the cleavage line, and
a fifth step of cleaving each of the plurality of laser bars along the device dividing line.

According to the above [10], the quality of cleavage along the device dividing groove or the cleavage introducing groove can be improved.

[11] In the method for manufacturing a semiconductor laser device of any one of [1] to [10], the second step includes a step of forming a resist film in which an opening portion overlapping a region including a central portion of a predetermined region where the device dividing groove is formed is provided on the first primary surface of the semiconductor member before the etching, and a thickness of the resist film at a peripheral edge portion of the opening portion is formed to be thinned toward an end portion of the opening portion along the second direction.

According to the above [11], the resist film is thinned with the progress of etching, and thus, the width of the opening portion of the resist film in the second direction can be gradually increased. As a result, the inner surface of the device dividing groove in the second direction can be formed to be inclined with respect to the thickness direction.

[12] The method for manufacturing a semiconductor laser device of [10] further includes a step of forming an insulating film provided to cover a top surface of the semiconductor layer of the semiconductor member and an inner surface of the device dividing groove, an opening portion in which a part of a top surface is exposed being provided in the insulating film, and forming an electrode covering at least a part of a portion of the insulating film that is in contact with the top surface via the opening portion and covers the top surface, after the second step and before the third step.

According to the above [12], in a case where the portion of the first inner surface of the device dividing groove formed by the semiconductor layer functions as the side surface of the mesa light emitting portion of the semiconductor laser device obtained after device division, since the side surface of the mesa light emitting portion can be appropriately protected by the insulating film, it is possible to suppress the occurrence of dark line defects due to damage to the side surface of the mesa light emitting portion. In addition, the electrode on the top surface of the semiconductor layer is formed via the insulating film, and thus, the adhesion of the electrode can be further improved. As a result, the manufacturing quality of the semiconductor laser device can be improved.

[13] There is provided a semiconductor laser device including
a semiconductor substrate, and
a semiconductor stacked body including an active layer and stacked on the semiconductor substrate.

A first side surface of the semiconductor stacked body in a second direction perpendicular to a first direction parallel to an optical waveguide direction of the semiconductor stacked body as viewed from a thickness direction of the semiconductor substrate is continuously provided with a second side surface of the semiconductor substrate in the second direction,
the first side surface is inclined with the thickness direction from the semiconductor stacked body side toward the semiconductor substrate side along the thickness direction toward an outside in the second direction,
the second side surface includes:
   a first portion connected to the first side surface, continuous with the first side surface, and is inclined with respect to the thickness direction; and
   a second portion connected to the first portion opposite to a side on which the first side surface is positioned with respect to the first portion, and
an inclination angle of the first portion with respect to the thickness direction is larger than an inclination angle of the second portion with respect to the thickness direction.

Since the semiconductor laser device of the above [13] has a configuration that can be easily and accurately manufactured by the manufacturing method of the above [1], it is possible to improve the yield. Further, in a case where the first side surface functions as the side surface of the mesa light emitting portion, since the first side surface is formed as the inclined surface inclined with respect to the thickness direction, it is possible to suitably suppress oscillation in a lateral direction of the mesa light emitting portion (oscillation in the second direction).

According to one aspect of the present disclosure, it is possible to provide the method for manufacturing a semiconductor laser device and the semiconductor laser device capable of shortening the time required for device division and improving the accuracy of device division.

### BRIEF DESCRIPTION OF THE DRAWINGS

FIG. 1 is a plan view of a semiconductor laser device manufactured by a method for manufacturing a semiconductor laser device according to an embodiment;

FIG. 2 is a cross-sectional view of the semiconductor laser device taken along line II-II of FIG. 1;

FIG. 3 is a cross-sectional view schematically illustrating a stacked structure of a semiconductor stacked body of the semiconductor laser device in FIG. 1;

FIG. 4 is a plan view illustrating an example of a wafer prepared in a first step;

FIG. 5 is a partially enlarged plan view of the wafer including an example of a device dividing groove and a cleavage introducing groove formed in a second step and a third step;

FIG. 6 is a partial cross-sectional view of the wafer illustrating a state after a resist film is formed in the second step;

FIG. 7 is a partial cross-sectional view of the wafer illustrating a state after the device dividing groove is formed in the second step;

FIG. 8 is an SEM image of an example of the device dividing groove;

FIG. 9 is a perspective view illustrating an example of the device dividing groove;

FIG. 10A is a plan view of the device dividing groove of FIG. 9, and FIG. 10B is a partial cross-sectional view of the wafer taken along line B-B in FIG. 10A;

FIG. 11 is a partial cross-sectional view of the wafer illustrating a state after the front surface processing step is performed;

FIG. 12 is a partial cross-sectional view of the wafer illustrating a state after the back surface processing step is performed;

FIG. 13 is a diagram schematically illustrating a device dividing step;

FIG. 14 is a perspective view illustrating a modification example of the device dividing groove;

FIG. 15 is a cross-sectional view of a semiconductor laser device according to a first modification example; and

FIG. 16 is a cross-sectional view of a semiconductor laser device according to a second modification example.

### DETAILED DESCRIPTION

Hereinafter, an embodiment of the present disclosure will be described in detail with reference to the drawings. Note that, in the following description, identical or equivalent devices are denoted by identical reference numerals, and redundant description thereof will be omitted. The drawings may be partially simplified or exaggerated for ease of understanding, and dimensional ratios are not limited to those described in the drawings.

### [Semiconductor Laser Device]

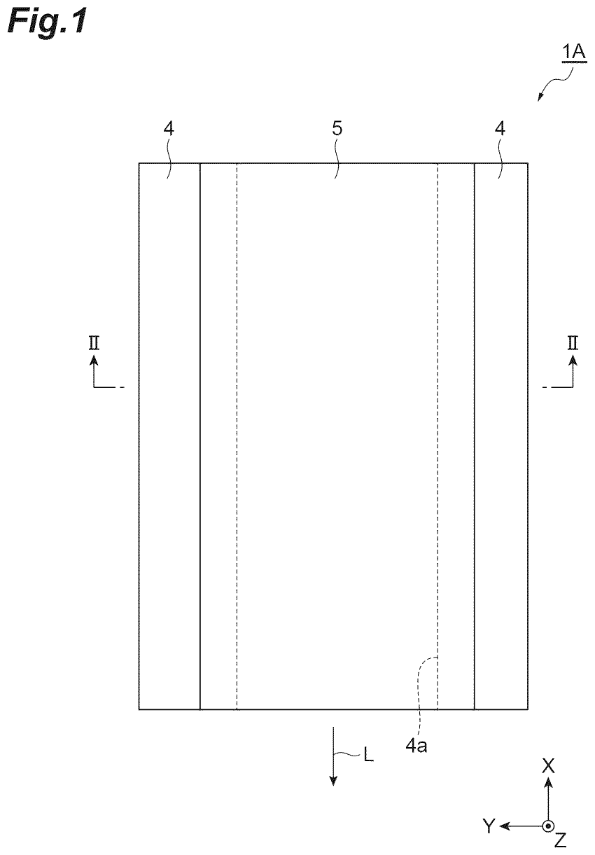

An example of a semiconductor laser device (semiconductor laser device 1A) manufactured by a method for manufacturing a semiconductor laser device according to an embodiment will be described with reference to FIGS. 1 to 3. As illustrated in FIGS. 1 to 3, the semiconductor laser device 1A includes a semiconductor substrate 2 and a semiconductor stacked body 3 stacked on the semiconductor substrate 2. In the present specification, for the sake of convenience, an XYZ orthogonal coordinate system in which a direction parallel to a thickness direction of the semiconductor substrate 2 is a Z-axis direction, a direction parallel to an optical waveguide direction (resonator length direction) of the semiconductor stacked body 3 is an X-axis direction (first direction), and a direction perpendicular to the optical waveguide direction (X-axis direction) as viewed from the thickness direction (Z-axis direction) is a Y-axis direction (second direction) is defined. The Z-axis direction is also a direction in which the semiconductor substrate 2 and the semiconductor stacked body 3 face each other, and is also a stacking direction of a plurality of layers included in the semiconductor stacked body 3. Note that, the first direction may be a direction in which a pair of end surfaces intersecting the optical waveguide direction face each other. In addition, the first direction may be a direction perpendicular to an emission end surface of a laser beam.

The semiconductor laser device 1A is, for example, an end surface emitting type laser diode that causes a laser beam to resonate between end surfaces of the semiconductor stacked body 3 facing each other in the X-axis direction and emits a laser beam L from one end surface along the X-axis direction. A length (resonator length) of the semiconductor laser device 1A in the X-axis direction is, for example, 0.5 mm to 2.0 mm, and is 1.0 mm as an example in the present embodiment. A width of the semiconductor laser device 1A in the Y-axis direction is, for example, 300 μm to 1000 μm, and is 500 μm as an example in the present embodiment. As an example, the semiconductor substrate 2 is a GaAs substrate made of GaAs. The semiconductor substrate 2 has a front surface 2a on which the semiconductor stacked body 3 is formed, a back surface 2b opposite to the front surface 2a, and a side surface 2c (second side surface) that intersects the Y-axis direction as a whole and connects the front surface 2a and the back surface 2b. The front surface 2a of the semiconductor substrate 2 is a (100) plane. That is, the Z-axis direction orthogonal to the front surface 2a is a direction parallel to a direction of the semiconductor substrate 2.

The semiconductor stacked body 3 is formed on the front surface 2a of the semiconductor substrate 2. The semiconductor stacked body 3 has a top surface 3a opposite to a side facing the front surface 2a, and a side surface 3b (first side surface) intersecting the Y-axis direction. The side surface 3b is provided continuously with the side surface 2c of the semiconductor substrate 2. That is, the side surface 3b is smoothly coupled to the side surface 2c at a connection portion (boundary portion) between the side surface 3b and the side surface 2c. The side surface 3b of the semiconductor stacked body 3 and a portion of the side surface 2c of the semiconductor substrate 2 continuous with the side surface 3b are formed as inclined surfaces inclined with respect to the Z-axis direction by etching in a device dividing groove forming step (second step) to be described later. More specifically, the side surface 3b is inclined with respect to the Z-axis direction toward an outside in the Y-axis direction from the semiconductor stacked body 3 side toward the semiconductor substrate 2 side along the Z-axis direction. As a result, the semiconductor stacked body 3 is formed in a mesa shape.

The side surface 2c of the semiconductor substrate 2 includes a first portion 2cl, a second portion 2c2, a third portion 2c3, and a fourth portion 2c4. The first portion 2cl is a portion that is connected to the side surface 3b of the semiconductor stacked body 3, is continuous with the side surface 3b, and is inclined with respect to the Z-axis direction. The second portion 2c2 is a portion that is connected to the first portion 2cl opposite to a side on which the side surface 3b is positioned with respect to the first portion 2cl. The third portion 2c3 is a portion that is connected to an end portion of the back surface 2b in the Y-axis direction and extends substantially parallel to the Z-axis direction. The fourth portion 2c4 is a portion that slightly extends in the Y-axis direction to connect an end portion of the second portion 2c2 opposite to a side connected to the first portion 2cl and an end portion of the fourth portion 2c4 opposite to a side connected to the back surface 2b.

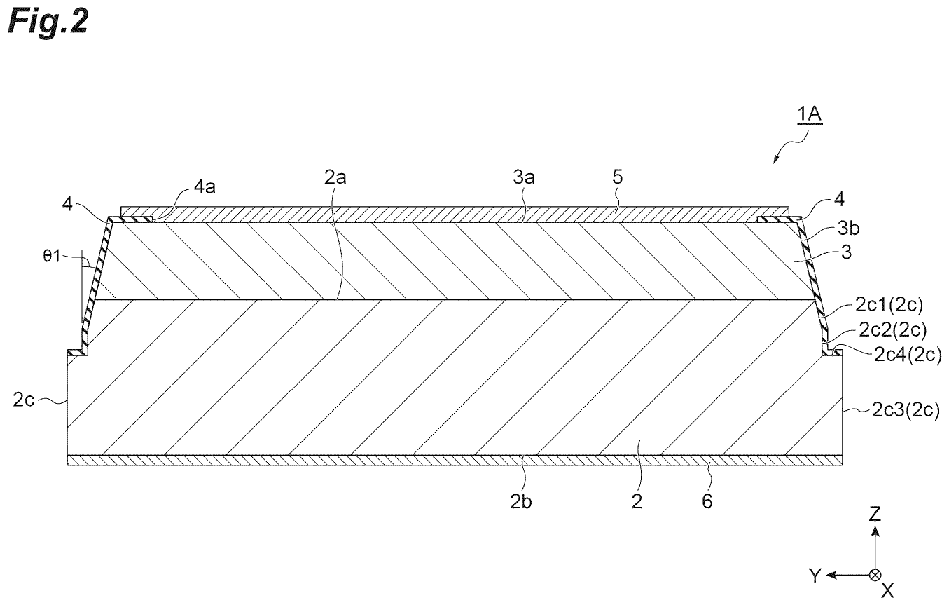

An inclination angle θ1 (see FIG. 2) of the first portion 2cl with respect to the Z-axis direction is larger than an inclination angle of the second portion 2c2 with respect to the Z-axis direction. As an example, the second portion 2c2 extends substantially parallel to the Z-axis direction, and the inclination angle of the second portion 2c2 with respect to the Z-axis direction is substantially 0 degrees. On the other hand, the inclination angle θ1 is, for example, 5 degrees to 25 degrees. Note that, as described above, since the first portion 2cl is provided continuously with the side surface 3b, an inclination angle of the side surface 3b with respect to the Z-axis direction substantially coincides with the inclination angle θ1 of the first portion 2c1.

An edge portion of the top surface 3a of the semiconductor stacked body 3 in the Y-axis direction, the entire side surface 3b of the semiconductor stacked body 3, and a portion of the side surface 2c of the semiconductor substrate 2 excluding the third portion 2c3 are covered with an insulating film 4. The insulating film 4 can be made from, for example, a silicon nitride film or a silicon oxide film. An opening portion 4a for exposing a part of the top surface 3a (in the present embodiment, a central portion of the top surface 3a in the Y-axis direction) is provided in a portion of the insulating film 4 covering the top surface 3a. The opening portion 4a has a constant width in the Y-axis direction and extends in the X-axis direction.

An electrode 5 on the front surface side of the semiconductor laser device 1A is formed to be in contact with the top surface 3a via the opening portion 4a of the insulating film 4 and to cover at least a part of the portion of the insulating film 4 covering the top surface 3a. A contact surface between the electrode 5 and the top surface 3a extends in the X-axis direction, and laser resonance occurs along the X-axis direction. An electrode 6 on the back surface side of the semiconductor laser device 1A is provided on the back surface 2b of the semiconductor substrate 2. The electrode 5 can be made of, for example, Ti/Pt/Au. The electrode 6 can be made of, for example, AuGe/Ni/Au.

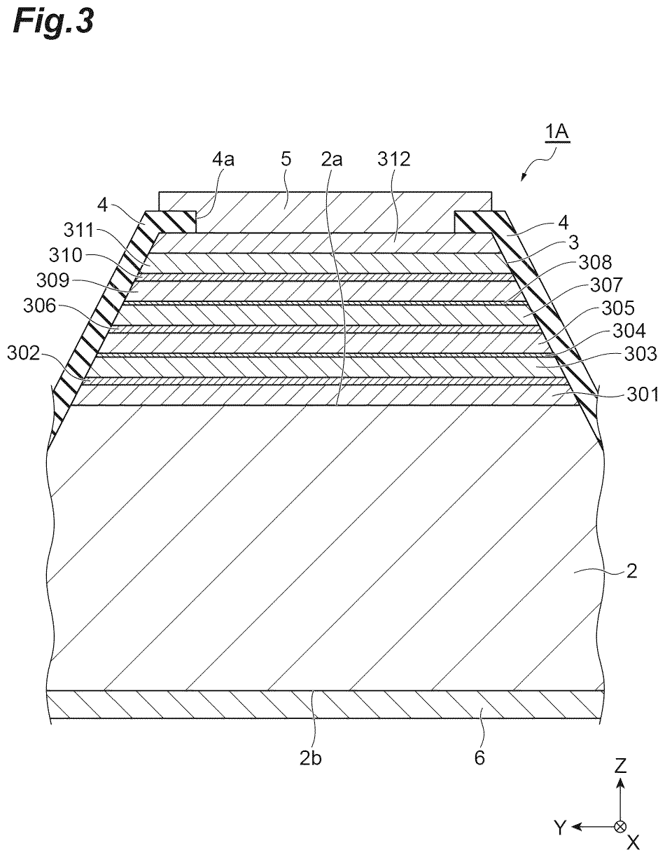

As illustrated in FIG. 3, the semiconductor stacked body 3 includes, as an example, a lower first cladding layer 301, a lower active layer 302 (active layer), a lower second cladding layer 303, a lower tunnel barrier layer 304, an intermediate first cladding layer 305, an intermediate active layer 306 (active layer), an intermediate second cladding layer 307, an intermediate tunnel barrier layer 308, an upper first cladding layer 309, an upper active layer 310 (active layer), an upper second cladding layer 311, and a contact layer 312 which are laminated in this order on the front surface 2a of the semiconductor substrate 2. The semiconductor stacked body 3 can be formed by growing these layers on the front surface 2a of the semiconductor substrate 2 by using, for example, a metalorganic chemical vapor deposition (MOCVD) method.

In the present embodiment, as an example, the semiconductor stacked body 3 includes a plurality of (here, three) active layers. The semiconductor laser device 1A can be regarded as a series connection of a first laser diode including the upper first cladding layer 309, the upper active layer 310, and the upper second cladding layer 311, a second laser diode including the intermediate first cladding layer 305, the intermediate active layer 306, and the intermediate second cladding layer 307, and a third laser diode including the lower first cladding layer 301, the lower active layer 302, and the lower second cladding layer 303. A current flows in a forward direction from the electrode 5 (an electrode on a P-type semiconductor side) toward the electrode 6 (an electrode on an N-type semiconductor side), each of the first to third laser diodes emits light and emits the laser beam L in the X-axis direction.

Examples of a combination of a thickness of each layer constituting the semiconductor stacked body 3, a suitable range of the thickness, and a conductivity type is shown in Table 1.

TABLE 1

| | Thickness | Suitable range of | Conductive |
|---|---|---|---|
| Device | μm | thickness (μm) | type |
| Contact layer 312 | 0.2 | 0.05 or more and | P |
| | | 2.0 or less | |
| Upper second cladding | 2.0 | 1.5 or more and | P |
| layer 311 | | 3.0 or less | |
| Upper active layer 310 | 0.02 | 0.01 or more and | |
| | | 0.1 or less | |
| Upper first cladding | 2.0 | 1.5 or more and | N |
| layer 309 | | 3.0 or less | |
| Intermediate tunnel | 0.2 | 0.05 or more and | |
| barrier layer 308 | | 0.4 or less | |
| Intermediate second | 2.0 | 1.5 or more and | P |
| cladding layer 307 | | 3.0 or less | |
| Intermediate active layer | 0.02 | 0.01 or more and | |
| 306 | | 0.1 or less | |
| Intermediate first | 2.0 | 1.5 or more and | N |
| cladding layer 305 | | 3.0 or less | |
| Lower tunnel barrier | 0.2 | 0.05 or more and | |
| layer 304 | | 0.4 or less | |
| Lower second cladding | 2.0 | 1.5 or more and | P |
| layer 303 | | 3.0 or less | |
| Lower active layer 302 | 0.02 | 0.01 or more and | |
| | | 0.1 or less | |
| Lower first cladding | 2.0 | 1.5 or more and | N |
| layer 301 | | 3.0 or less | |
| Semiconductor substrate | 120 | 90 or more and | N |
| 2 | | 150 or | |
| | | less | |

Examples of a combination of a material and an impurity concentration of each layer constituting the semiconductor stacked body 3 is shown in Table 2. The number of active layers stacked in the semiconductor stacked body 3 is not limited to three and may be four or more.

TABLE 2

| | | | Suitable range of |
|---|---|---|---|
| | | Impurity | impurity |
| | | concentration | concentration |
| Device | Material | (cm⁻³) | (cm⁻³) |
| Contact layer 312 | GaAs | 1 × 10²⁰ | 1 × 10¹⁹ or more |
| | | | 2 × 10²⁰ or less |
| Upper second cladding | AlGaAs | 1 × 10¹⁸ | 1 × 10¹⁷ or more |
| layer 311 | | | 2 × 10¹⁸ or less |
| Upper active layer 310 | InAlGaAs | Non-doped | — |
| Upper first cladding | AlGaAs | 1 × 10¹⁸ | 1 × 10¹⁷ or more |
| layer 309 | | | 2 × 10¹⁸ or less |
| Intermediate tunnel | GaAs | 1 × 10¹⁹ | 5 × 10¹⁸ or more |
| barrier layer 308 | | | 1 × 10²⁰ or less |
| Intermediate second | AlGaAs | 1 × 10¹⁸ | 1 × 10¹⁷ or more |
| cladding layer 307 | | | 2 × 10¹⁸ or less |
| Intermediate active | InAlGaAs | Non-doped | — |
| layer 306 | | | |
| Intermediate first | AlGaAs | 1 × 10¹⁸ | 1 × 10¹⁷ or more |
| cladding layer 305 | | | 2 × 10¹⁸ or less |
| Lower tunnel barrier | GaAs | 1 × 10¹⁹ | 5 × 10¹⁸ or more |
| layer 304 | | | 1 × 10²⁰ or less |
| Lower second cladding | AlGaAs | 1 × 10¹⁸ | 1 × 10¹⁷ or more |
| layer 303 | | | 2 × 10¹⁸ or less |
| Lower active layer 302 | InAlGaAs | Non-doped | — |
| Lower first cladding | AlGaAs | 1 × 10¹⁸ | 1 × 10¹⁷ or more |
| layer 301 | | | 2 × 10¹⁸ or less |
| Semiconductor | GaAs | 1 × 10¹⁸ | 5 × 10¹⁷ or more |
| substrate 2 | | | 2 × 10¹⁸ or less |

### [Method for Manufacturing Semiconductor Laser Device]

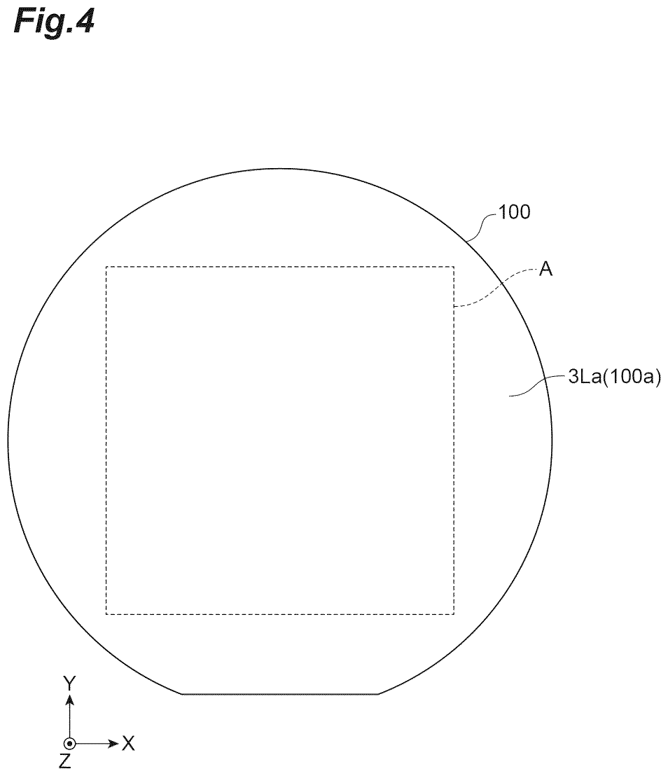

An example of a method for manufacturing the semiconductor laser device 1A will be described with reference to FIGS. 4 to 13.

### (First Step: Wafer Preparation Step)

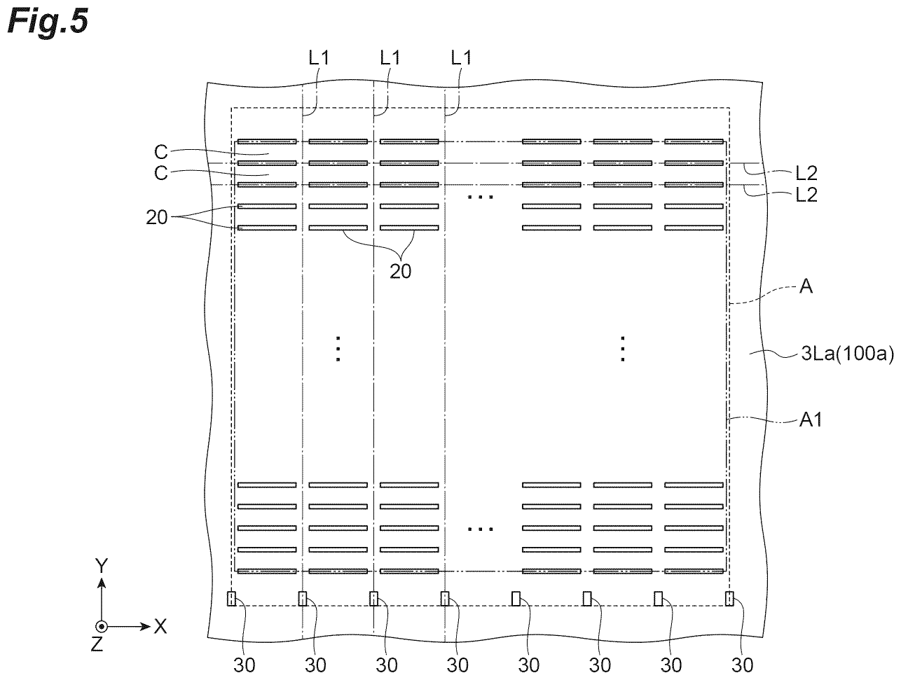

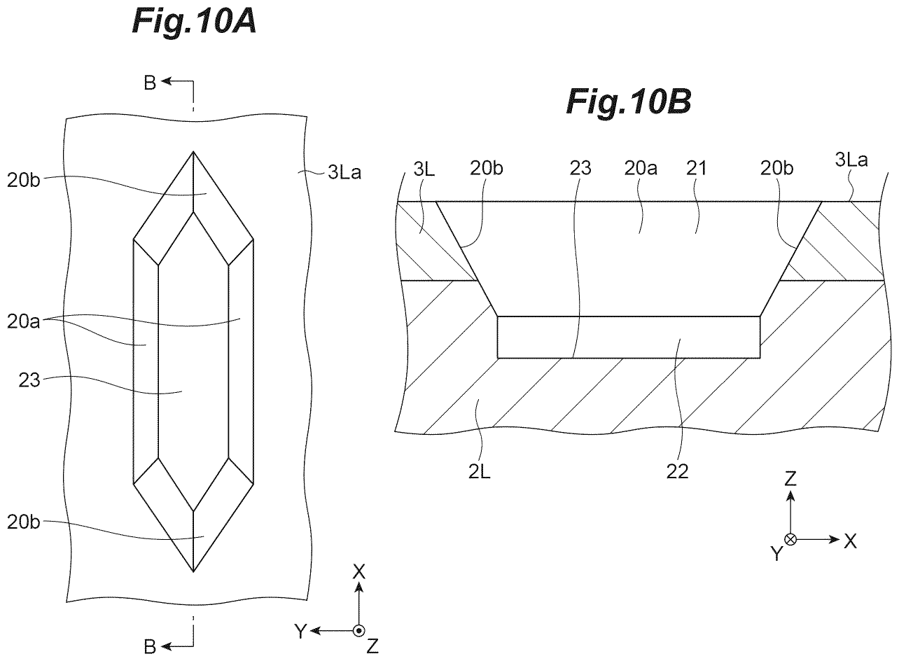

First, as illustrated in FIGS. 4 and 5, a disk-shaped wafer 100 (semiconductor member) including a plurality of device portions C to become semiconductor laser devices 1A is prepared. FIG. 5 is an enlarged plan view of a square region A in FIG. 4. The region A is, for example, a square region having one side of 30 mm. A central region of the region A in the Y-axis direction (that is, a region excluding both side edge portions of the region A in the Y-axis direction) is formed as a device region A1 in which the plurality of device portions C is disposed. An end portion of the device region A1 in the Y-axis direction coincides with an outer end portion of the semiconductor laser device 1A in the Y-axis direction (strictly speaking, a portion to become the semiconductor laser device 1A after device division) positioned on an outermost side in the Y-axis direction. In other words, a side portion along the end portion of the device region A1 in the Y-axis direction (an upper side and a lower side of the device region A1 in FIG. 5) coincides with a device dividing line L2 positioned on an outermost side in the Y-axis direction. Note that, in FIG. 5, a plurality of device dividing grooves 20 and a plurality of cleavage introducing grooves 30 formed in a device dividing groove forming step (second step) and a cleavage introducing groove forming step (third step) to be described later are illustrated. In addition, in FIG. 5, a shape of the device dividing groove 20 as viewed from the Z-axis direction is illustrated in a simple rectangular shape, but in the present embodiment, the device dividing groove 20 is actually formed in a boat shape as illustrated in FIG. 10A in plan view.

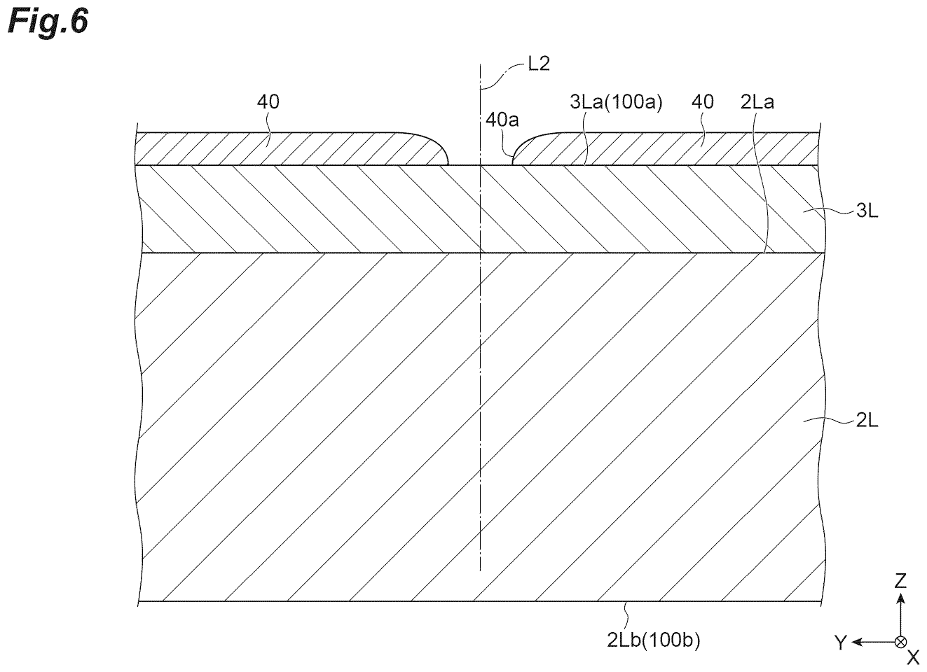

As illustrated in FIG. 6, the wafer 100 includes a substrate layer 2L and a semiconductor layer 3L. The substrate layer 2L is a layer including the semiconductor substrate 2 of each of the plurality of device portions C (that is, portions to become individual semiconductor laser devices 1A after device division). In other words, the substrate layer 2L has a structure in a state where the semiconductor substrate 2 of each of the plurality of device portions C extends continuously along an XY plane without being separated. The semiconductor layer 3L is a layer including the semiconductor stacked body 3 of each of the plurality of device portions C. In other words, the semiconductor layer 3L has a structure in a state where the semiconductor stacked body 3 of each of the plurality of device portions C continuously extends along the XY plane without being separated.

The substrate layer 2L has a front surface 2La and a back surface 2Lb that are portions to become the front surface 2a and the back surface 2b of the semiconductor substrate 2 of each of the individual semiconductor laser devices 1A after device division. The semiconductor layer 3L can be formed, for example, by growing the layers (layers corresponding to the layers 301 to 312 in FIG. 3) constituting the semiconductor layer 3L on the front surface 2La of the substrate layer 2L by using the MOCVD method described above. The semiconductor layer 3L has a top surface 3La that is a portion to become the top surface 3a of the semiconductor stacked body 3 of each of the individual semiconductor laser device 1A after device division. In the present embodiment, as an example, the front surface 2La of the substrate layer 2L is the (100) plane. In addition, a direction (that is, a Y-axis positive direction in FIG. 4) perpendicular to an orientation flat processed surface of the substrate layer 2L (a flat surface disposed on a lower side in FIG. 4) is a direction of the substrate layer 2L. An X-axis positive direction in FIG. 4 is a [01-1] direction of the substrate layer 2L.

The wafer 100 has a first primary surface 100a on a side on which the semiconductor layer 3L is positioned with respect to the substrate layer 2L, and a second primary surface 100b opposite to the first primary surface 100a. In the present embodiment, the first primary surface 100a is constituted by the top surface 3La of the semiconductor layer 3L. The second primary surface 100b is constituted by the back surface 2Lb of the substrate layer 2L.

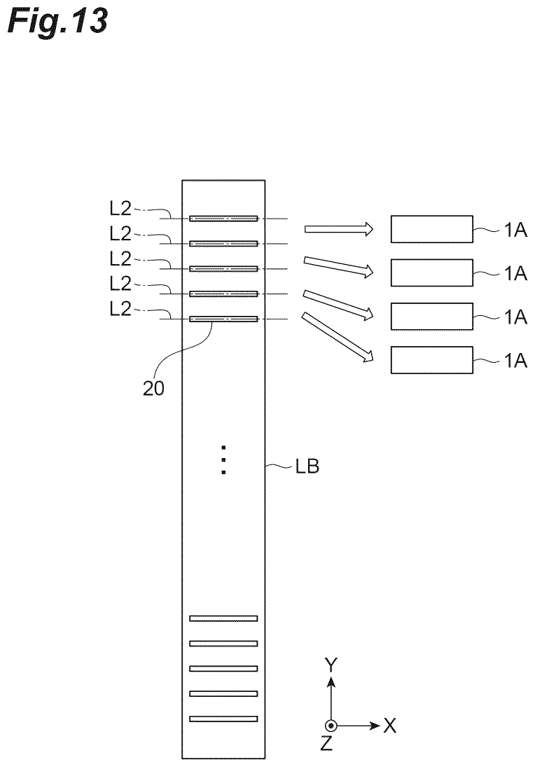

In the present embodiment, a plurality of device portions C are included inside the device region A1. The plurality of device portions C are arrayed in a matrix in the X-axis direction and the Y-axis direction. As illustrated in FIG. 5, a plurality of cleavage lines L1 extending in the Y-axis direction are set in the wafer 100 to partition the plurality of device portions C arrayed in the X-axis direction (that is, to partition two device portions C adjacent to each other in the X-axis direction). In addition, in the wafer 100, a plurality of device dividing lines L2 extending in the X-axis direction are set to partition the plurality of device portions C arrayed in the Y-axis direction (that is, to partition two device portions C adjacent to each other in the Y-axis direction). The cleavage lines L1 are lines along which the wafer 100 is to be divided in a primary cleavage step (fourth step) to be described later. The device dividing lines L2 are lines along which a laser bar LB (see FIG. 13) is to be divided in a secondary cleavage step (fifth step) to be described later.

An extending direction (that is, the X-axis direction) of each of the plurality of device dividing lines L2 is set to be parallel to the [01-1] direction of the substrate layer 2L. According to the above configuration, the device dividing lines L2 of the secondary cleavage (fifth step) are aligned with the [01-1] direction of the substrate layer 2L which is a crystal orientation in which cracking is difficult, and thus, the mechanical strength of the wafer 100 after the device dividing grooves 20 are formed can be suitably secured in the device dividing groove forming step (second step) to be described later. As a result, in a case where a back surface processing (for example, back surface processing step to be described later) is performed before the primary cleavage (fourth step), it is possible to suitably suppress damage to the wafer 100. That is, since the back surface processing or the like can be performed in a state where certain mechanical strength is secured, it is possible to reduce a risk of unexpected damage of the wafer 100 during the back surface processing or the like or when the wafer 100 is carried to perform the back surface processing or the like.

### (Second Step: Device Dividing Groove Forming Step)

Subsequently, as illustrated in FIG. 5, the device dividing grooves 20 are formed by etching on the first primary surface 100a of the wafer 100 along each of the plurality of device dividing lines L2. The etching is dry etching using a chlorine-based gas. For example, the device dividing grooves 20 can be formed by reactive ion etching (RIE) using inductively coupled plasma (ICP). The dry etching using the chlorine-based gas is used, and thus, it is possible to easily and accurately perform vertical etching. As a result, it is possible to accurately control the shape of the device dividing groove 20.

The device dividing grooves 20 are individually formed in regions between the plurality of device portions C adjacent to each other in the X-axis direction not to straddle the cleavage lines L1. That is, an etching groove is not formed on the cleavage line L1. In the present embodiment, as an example, a distance between cleavage lines L1 adjacent to each other in the X-axis direction is 1.0 mm (that is, the resonator length of the semiconductor laser device 1A described above), and a length of the device dividing groove 20 in the X-axis direction is 0.8 mm. A center of the device dividing groove 20 in the X-axis direction substantially coincides with a center of a region in the X-axis direction (that is, the device portion C) between the cleavage lines L1 adjacent to each other in the X-axis direction. That is, in the present embodiment, a separation distance (distance in the X-axis direction) between an end portion of the device dividing groove 20 in the X-axis direction and the cleavage line L1 closest to the end portion is 0.1 mm. Note that, the length of the device dividing groove 20 in the X-axis direction can be selected from, for example, a range of 0.8 mm to 0.95 mm.

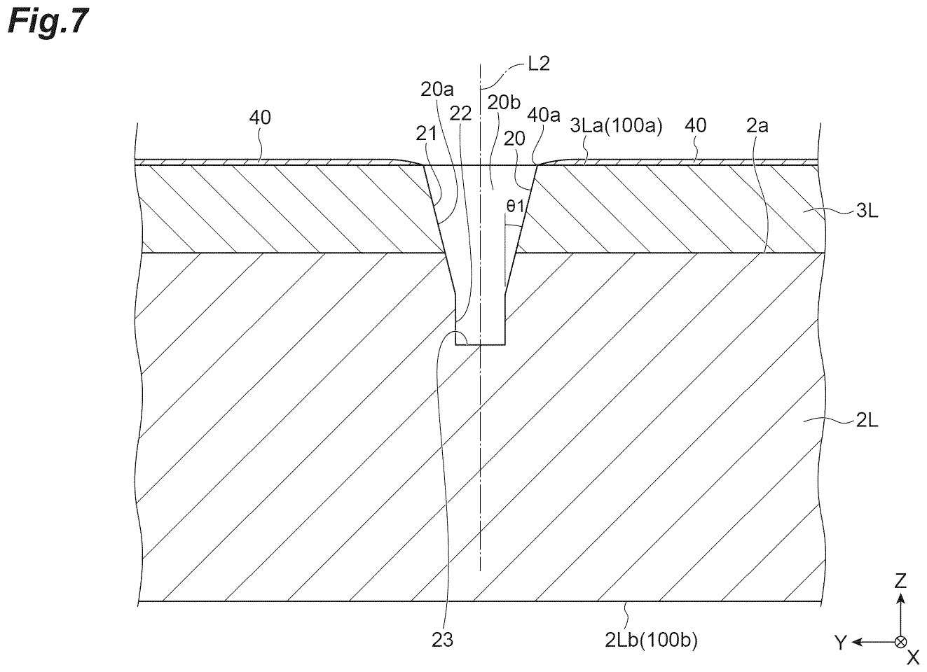

An example of the device dividing groove forming step and an example of the device dividing groove 20 formed by the device dividing groove forming step will be described in detail with reference to FIGS. 6 to 10B. FIGS. 6 and 7 illustrate a cross section of the wafer 100 at a position where the device dividing groove 20 is to be formed (a substantially central position of the device dividing groove 20 in the X-axis direction).

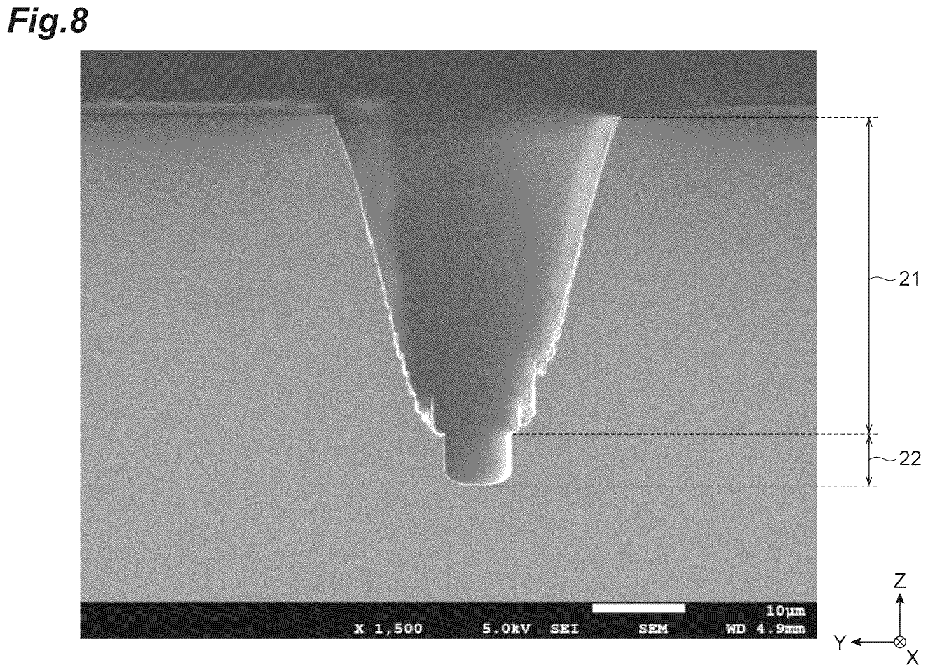

First, a configuration of the device dividing groove 20 will be described with reference to FIGS. 7 to 10B. As illustrated in FIG. 7, the device dividing groove 20 penetrates the semiconductor layer 3L and reaches the substrate layer 2L. In addition, as illustrated in FIGS. 7 and 8, the device dividing groove 20 includes a first portion 21 positioned on an opening side of the device dividing groove 20 and a second portion 22 positioned on a bottom portion side of the device dividing groove 20 with respect to the first portion 21. A bottom portion of the device dividing groove 20 has a bottom surface 23 extending substantially parallel to the Y-axis direction. In other words, the bottom portion of the device dividing groove 20 does not have a pointed shape like a V-shaped groove, and a substantially planar portion (bottom surface 23) having a constant width in the Y-axis direction is formed at the bottom portion of the device dividing groove 20.

A width of the bottom surface 23 in the Y-axis direction is preferably set to 20 μm or less, and more preferably set to 10 μm or less, from the viewpoint of securing the control accuracy in a development direction of a crack at the time of device division. In addition, from the viewpoint of securing the mechanical strength of the wafer 100 after the device dividing grooves 20 are formed, the width of the bottom surface 23 in the Y-axis direction is preferably set to 5 μm or more. An opening width of the device dividing groove 20 in the Y-axis direction (that is, a width of an upper end opening of the first portion 21 in the Y-axis direction) is preferably set to 10 μm or more. A depth of the device dividing groove 20 in the Z-axis direction (that is, a distance from an upper end of the first portion 21 to a bottom portion of the second portion 22) is preferably set to 20 μm or more. In the example of FIG. 8, the width of the bottom surface 23 in the Y-axis direction (=a width of the second portion 22 in the Y-axis direction) is 7.25 μm, the opening width of the device dividing groove 20 in the Y-axis direction is 31.2 μm, and the depth of the device dividing groove 20 in the Z-axis direction is 40.1 μm. In addition, in the present embodiment, a depth of the first portion 21 in the Z-axis direction (a length of the first portion 21 in the Z-axis direction) is larger than a depth of the second portion 22 in the Z-axis direction (a length of the second portion 22 in the Z-axis direction). The depth of the first portion 21 is increased, and thus, it is possible to efficiently increase a volume of the device dividing groove 20. As a result, it is possible to easily divide the device.

The device dividing groove 20 has a pair of inner surfaces 20a (first inner surfaces) in the Y-axis direction and a pair of inner surfaces 20b (second inner surfaces) in the X-axis direction. The pair of inner surfaces 20a are surfaces provided at positions facing each other in the Y-axis direction with a substantially central portion of the device dividing groove 20 interposed therebetween as viewed from the Z-axis direction. The pair of inner surfaces 20b are surfaces provided at positions facing each other in the X-axis direction with a substantially central portion of the device dividing groove 20 interposed therebetween as viewed from the Z-axis direction.

As illustrated in FIG. 7, at least a portion of the inner surface 20a formed by the semiconductor layer 3L is inclined with respect to the Z-axis direction such that the width of the device dividing groove 20 in the Y-axis direction decreases from the first primary surface 100a side toward the second primary surface 100b side. In the present embodiment, the inner surface 20a of the first portion 21 is inclined with respect to the Z-axis direction such that the width of the device dividing groove 20 in the Y-axis direction decreases from the first primary surface 100a side toward the second primary surface 100b side. In addition, an inclination angle θ1 of the inner surface 20a of the first portion 21 with respect to the Z-axis direction is larger than an inclination angle of the inner surface 20a of the second portion 22 with respect to the Z-axis direction. As an example, the inner surface 20a of the second portion 22 extends substantially parallel to the Z-axis direction, and an inclination angle of the inner surface 20a of the second portion 22 with respect to the Z-axis direction is substantially 0 degrees. Note that, the inner surface 20a of the first portion 21 is a portion corresponding to the side surface 3b and the first portion 2cl of the side surface 2c of the semiconductor laser device 1A obtained after device division. The inner surface 20a of the second portion 22 is a portion corresponding to the second portion 2c2 of the side surface 2c of the semiconductor laser device 1A obtained after device division.

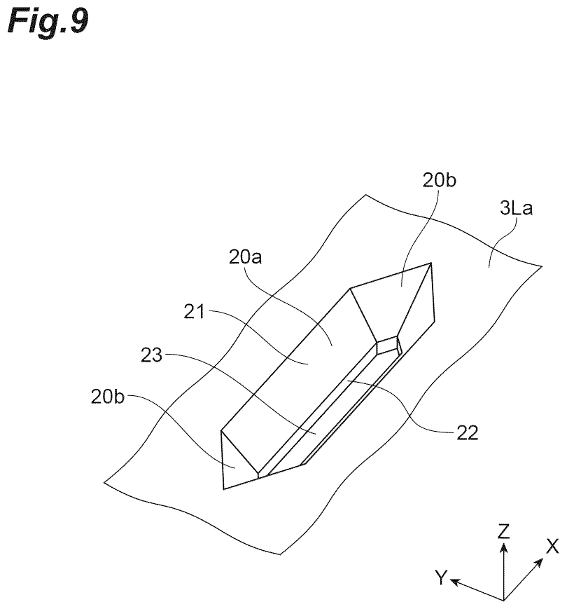

As illustrated in FIGS. 9, 10A, and 10B, the inner surface 20b of the device dividing groove 20 is inclined with respect to the Y-axis direction to become narrower toward a substantially central portion of the device dividing groove 20 in the Y-axis direction toward an outside in the X-axis direction. In the present embodiment, as an example, the inner surface 20b of the device dividing groove 20 is formed in a boat shape inclined with respect to the Y-axis direction to become narrower toward a substantially central portion of the device dividing groove 20 in the Y-axis direction toward the outside in the X-axis direction in both the first portion 21 and the second portion 22.

Next, an example of a method for forming the device dividing groove 20 in the above-described shape will be described. As illustrated in FIG. 6, the device dividing groove forming step includes a step of forming a resist film 40 on the first primary surface 100a (the primary surface on which the device dividing groove 20 is formed) of the wafer 100 before etching. An opening portion 40a that overlaps with a central portion of a region where the device dividing groove 20 is to be formed is provided in the resist film 40. The opening portion 40a defines a size of the second portion 22 of the device dividing groove 20 to be described later as viewed in the Z-axis direction. More specifically, a width of the second portion 22 of the device dividing groove 20 in the Y-axis direction obtained after the device dividing groove forming step is slightly larger than a width of the opening portion 40a in the Y-axis direction before the start of etching. Similarly, a width of the second portion 22 of the device dividing groove 20 in the X-axis direction obtained after the device dividing groove forming step is slightly larger than a width of the opening portion 40a in the X-axis direction before the start of etching. In the example of FIG. 8, the width of opening portion 40a in the Y-axis direction before the start of etching is set to 5 μm, and thus, the width of the bottom surface 23 in the Y axis direction (=the width of second portion 22 in the Y-axis direction) is adjusted to 7.25 μm.

As illustrated in FIG. 7, a thickness of the resist film 40 at a peripheral edge portion of the opening portion 40a is formed to decrease toward an end portion of the opening portion 40a along the Y-axis direction. According to the above configuration, the resist film 40 is thinned with the progress of etching, and thus, the width of the opening portion 40a of the resist film 40 in the Y-axis direction can be gradually increased. As a result, it is possible to easily form the inner surface 20a of the device dividing groove 20 in the Y-axis direction to be inclined with respect to the Z-axis direction. That is, it is possible to easily form the inner surface 20a of the first portion 21 described above. In addition, etching progresses in a vertical direction (Z-axis direction) until a portion of an edge portion of the opening portion 40a of the resist film 40 is reduced and the opening portion 40a starts to spread in the Y-axis direction after etching is started. As a result, it is possible to easily form the second portion 22 extending substantially perpendicularly to the Z-axis direction as viewed in the X-axis direction.

In addition, as illustrated in FIGS. 9, 10A, and 10B, in the present embodiment, the inner surface 20b of the first portion 21 is inclined with respect to the Z-axis direction such that the width of the device dividing groove 20 in the X-axis direction decreases from the first primary surface 100a side toward the second primary surface 100b side. In addition, an inclination angle of the inner surface 20b of the first portion 21 with respect to the Z-axis direction is larger than an inclination angle (in the present embodiment, approximately 0 degrees) of the inner surface 20b of the second portion 22 with respect to the Z-axis direction. It is also possible to easily form such a shape by the method using the resist film 40 as described above. That is, the thickness of the resist film 40 at the peripheral edge portion of the opening portion 40a may be formed to decrease toward the end portion of the opening portion 40a along the X-axis direction. According to the above configuration, the resist film 40 is thinned with the progress of etching, and thus, the width of the opening portion 40a of the resist film 40 in the X-axis direction can be gradually increased. As a result, it is possible to form the inner surface 20b of the device dividing groove 20 in the X-axis direction to be inclined with respect to the Z-axis direction. That is, it is possible to easily form the inner surface 20b of the first portion 21 described above. In addition, etching progresses in the vertical direction (Z-axis direction) until the portion of the edge portion of the opening portion 40a of the resist film 40 is reduced and the opening portion 40a starts to spread in the X-axis direction after etching is started. As a result, it is possible to easily form the second portion 22 extending substantially perpendicularly to the Z-axis direction as viewed in the Y-axis direction.

The semiconductor layer 3L of each device portion C is formed in a mesa shape by being separated into the semiconductor layers 3L of the device portions C adjacent to each device portion C by the device dividing groove 20 formed on both sides of each device portion C in the Y-axis direction. That is, in the present embodiment, the device dividing groove forming step also serves as a mesa forming step for forming a mesa portion.

### (Front Surface Processing Step)

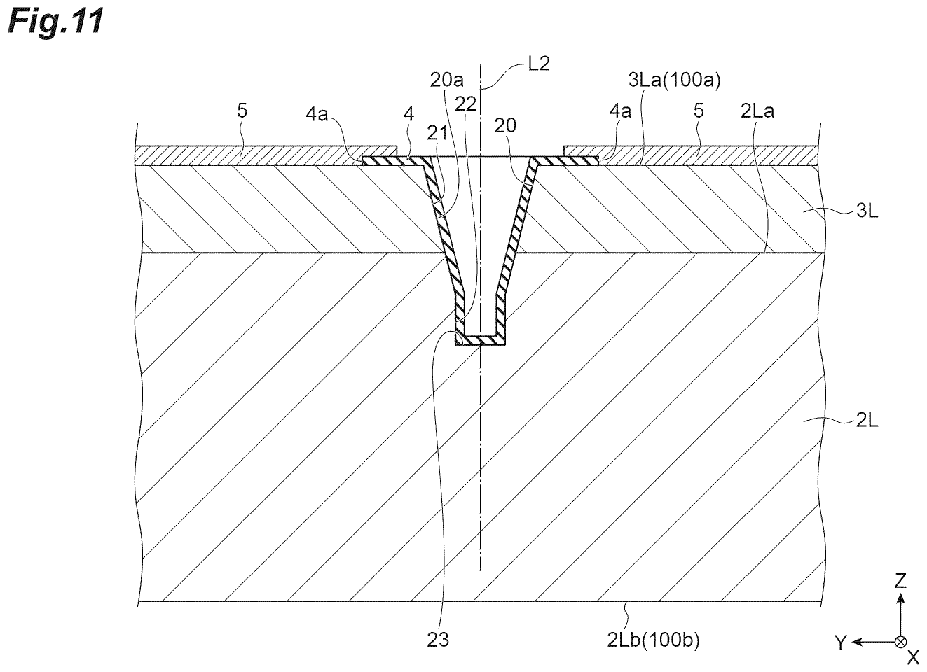

Subsequently, as illustrated in FIG. 11, a front surface processing step (front surface process) is performed. First, the insulating film 4 is formed to cover the top surface 3La of the semiconductor layer 3L of the wafer 100 and the inner surfaces 20a and 20b of the device dividing grooves 20. The opening portion 4a that exposes a part of the top surface 3La is provided in the insulating film 4. The insulating film 4 is formed to extend in the X-axis direction along each of the plurality of device dividing lines L2 inside the device region A1 (see FIG. 5), for example. Subsequently, the electrode 5 is formed to be in contact with the top surface 3La via the opening portion 4a and cover at least a part of a portion of the insulating film 4 covering the top surface 3La. For example, inside the device region A1, the electrode 5 is formed to extend in the X-axis direction along a central portion of each device portion C between the device dividing lines L2 and L2 adjacent to each other.

In the present embodiment, the inner surface 20a of the first portion 21 of the device dividing groove 20 has a shape expanding toward the opening side of the device dividing groove 20. Thus, in a case where the insulating film 4 is formed by the CVD method or the like, since gas easily enters the inside of the first portion 21, it is possible to suitably form the insulating film 4 on the inner surface 20a of the first portion 21. In addition, since the first portion 21 penetrates the semiconductor layer 3L and reaches the substrate layer 2L, it is possible to reliably form the insulating film 4 on the entire inner surface 20a of the semiconductor layer 3L including the active layer. On the other hand, on a back side of the first portion 21, gas hardly enters the inside of the second portion 22 that is not inclined with respect to the Z-axis direction than the first portion 21. Thus, it is possible to set the thickness of the insulating film 4 formed on the second portion 22 and the bottom surface 23 to be smaller than the thickness of the insulating film 4 formed on the first portion 21. As a result, it is possible to reduce a possibility that the insulating film 4 formed on the bottom surface 23 adversely influences device division.

### (Back Surface Processing Step)

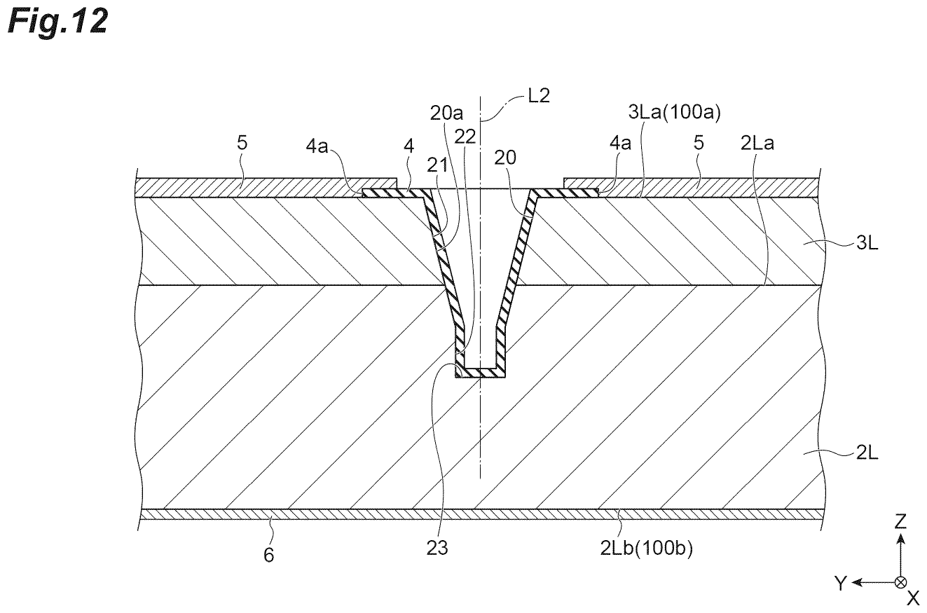

Subsequently, as illustrated in FIG. 12, the back surface processing step (back surface process) is performed. First, the back surface 2Lb of the substrate layer 2L of the wafer 100 is scrapped, and thus, thinning processing of the wafer 100 (substrate layer 2L) is performed. Subsequently, the electrode 6 is formed on the back surface 2Lb of the thinned substrate layer 2L. The electrode 6 is formed, for example, on the entire back surface 2Lb of the device region A1.

### (Third Step: Cleavage Introducing Groove Forming Step)

Subsequently, as illustrated in FIG. 5, at a position overlapping each of the plurality of cleavage lines L1, the cleavage introducing groove 30 serving as a starting point of a cleavage is formed on the first primary surface 100a or the second primary surface 100b. The cleavage introducing groove 30 is formed outside the device region A1 where the plurality of device portions C are disposed. That is, the cleavage introducing groove 30 is not formed between the plurality of device portions C adjacent to each other in the X-axis direction (that is, a region overlapping the cleavage line L1 inside the device region A1).

The cleavage introducing groove 30 can be formed by, for example, diamond scribing or the like scribed with a diamond tool. In the present embodiment, the plurality of cleavage introducing grooves 30 are formed on the first primary surface 100a where the plurality of device dividing grooves 20 are formed. That is, in the present embodiment, both the device dividing groove 20 and the cleavage introducing groove 30 are formed on the first primary surface 100a. According to the above configuration, the quality of cleavage along the device dividing groove 20 or the cleavage introducing groove 30 can be improved. More specifically, since the electrode 6 is formed on the entire second primary surface 100b as described above, in a case where a scribed groove (device dividing groove or cleavage introducing groove) is provided by performing scribing on the second primary surface 100b from above the electrode 6, it is not possible to accurately form the scribed groove due to the presence of the electrode 6, and sufficient cleavage quality may not be obtained. In addition, in order to avoid deterioration of cleavage quality as described above, it is conceivable to pattern the electrode 6 to avoid a position where the scribed groove is formed, but in this case, a man-hour increase by the amount of the patterning. On the other hand, the device dividing groove 20 and the cleavage introducing groove 30 are formed in the first primary surface 100a as described above, and thus, it is possible to avoid the above-described disadvantage.

### (Fourth Step: Primary Cleavage Step)

Subsequently, the wafer 100 is cut along an outer edge portion of the region A to obtain a square plate-shaped member including only the region A of the wafer 100. Note that, such cutting can be performed by a known method. For example, a portion of the outer edge portion of the region A along the Y-axis direction (that is, a portion of the region A along the cleavage lines L1 on both sides in the X-axis direction) may be cleaved by processing similar to the primary cleavage to be described later. In addition, a portion of the outer edge portion of the region A along the X-axis direction may be cut by performing breaking processing of pressing and breaking the wafer 100 by applying a breaking blade from the back surface (second primary surface 100b) side of the wafer 100 after being scribed by diamond scribing or the like.

Subsequently, processing (primary cleavage) of cleaving the wafer 100 (in the present embodiment, the square plate-shaped member obtained by the above-described method) along each of the plurality of cleavage lines L1 is executed. As a result, the plurality of laser bars LB (see FIG. 13) each including the plurality of device portions C one-dimensionally arrayed in the Y-axis direction are obtained. The above primary cleavage is executed, for example, by performing the breaking processing of pressing and breaking the wafer 100 by applying the breaking blade from the back surface (second primary surface 100b) side of the wafer 100 along the cleavage line L1 as described above.

### (Fifth Step: Secondary Cleavage Step)

Subsequently, processing (secondary cleavage or device division) of cleaving each of the plurality of laser bars LB along each of the plurality of device dividing lines L2 is executed. As a result, as illustrated in FIG. 13, a plurality of semiconductor laser devices 1A are obtained from each laser bar LB. The above secondary cleavage is performed, for example, by performing the breaking processing of pressing and breaking the wafer 100 by applying the breaking blade from the back surface (second primary surface 100b) side of the laser bar LB along the device dividing line L2 as described above.

### [Effects]

In the method for manufacturing the semiconductor laser device 1A, the device dividing groove 20 for the secondary cleavage (fifth step) is formed at a stage (second step) in a wafer state before the plurality of laser bars LB are obtained by the primary cleavage (fourth step). As a result, it is not necessary to perform scribing processing for each laser bar LB by using a diamond tool, a laser, or the like as pre-processing for the secondary cleavage (fifth step) after the primary cleavage (fourth step). In addition, since a man-hour of the second step (that is, the processing of forming the device dividing groove 20 in the wafer state) is smaller than a man-hour required to execute the scribing processing for each laser bar LB as described above, it is possible to reduce a work man-hour by the manufacturing method. In addition, since the device dividing groove 20 is formed by etching, a deep damage layer generated in a case where point scribing (diamond scribing) is performed or the like is not formed at a distal end portion (bottom portion) of the device dividing groove 20 in the Z-axis direction. As a result, it is possible to sufficiently secure the strength of the wafer 100 after the device dividing grooves 20 are formed. As a result, even in a case where the back surface processing or the like of the wafer 100 is performed after the second step, the wafer 100 is appropriately prevented from being damaged. In addition, in a case where point scribing is performed, problems such as scattering of debris and occurrence of lateral cracks may occur, but it is possible to reliably avoid the above problems by forming the device dividing grooves 20 by etching. In addition, the device dividing groove 20 (etching groove) is not formed on the cleavage line L1, and the cleavage introducing groove 30 is also formed mainly outside the device region A1. That is, the groove is not formed on the cleavage line L1 in the device region A1. As a result, it is possible to suppress the occurrence of cracks (cracks developing in the X-axis direction) caused by the groove in the laser bar LB obtained by the primary cleavage (fourth step). In addition, the semiconductor substrate 2 made of GaAs (that is, the substrate layer 2L made of GaAs) which is relatively easily cracked is used, and thus, the primary cleavage (fourth step) along the cleavage line L1 can be easily and accurately performed only by providing the cleavage introducing groove 30 outside the device region A1. Accordingly, according to the above manufacturing method, it is possible to reduce the man-hour at the time of manufacturing without impairing the manufacturing quality of the semiconductor laser device 1A.

In addition, the cleavage introducing groove 30 is not formed inside the device region A1 (in particular, the region between the device portions C adjacent to each other in the X-axis direction on the cleavage line L1). That is, neither the device dividing groove 20 nor the cleavage introducing groove 30 is formed on the cleavage line L1 in the device region A1. As a result, it is possible to more effectively suppress the occurrence of the cracks of the laser bar LB in the above-described primary cleavage (fourth step).

In addition, the device dividing groove 20 is formed in the first primary surface 100a, penetrates the semiconductor layer 3L, and reaches the substrate layer 2L. At least a portion of the inner surface 20a of the device dividing groove 20 formed by the semiconductor layer 3L is inclined with respect to the Z-axis direction such that the width of the device dividing groove 20 in the Y-axis direction decreases from the first primary surface 100a side toward the second primary surface 100b side. According to the above configuration, in a case where the portion of the inner surface 20a of the device dividing groove 20 formed by the semiconductor layer 3L functions as a side surface of a mesa light emitting portion of the semiconductor laser device 1A, it is possible to suitably suppress oscillation of the mesa light emitting portion in a lateral direction (oscillation in the Y-axis direction). In addition the device dividing groove 20 reaches the substrate layer 2L, and thus, only the substrate layer 2L may be divided in the secondary cleavage (fifth step). As a result, it is possible to reduce a risk of occurrence of cracks inside the semiconductor layer 3L at the time of the secondary cleavage or peeling of the semiconductor layer 3L from the substrate layer 2L.

In addition, the inner surface 20a of the first portion 21 is inclined with respect to the Z-axis direction such that the width of the device dividing groove 20 in the Y-axis direction decreases from the first primary surface 100a side toward the second primary surface 100b side, the inclination angle θ1 of the inner surface 20a of the first portion 21 with respect to the Z-axis direction is larger than the inclination angle (in the present embodiment, approximately 0 degrees) of the inner surface 20a of the second portion 22 with respect to the Z-axis direction, and the first portion 21 penetrates the semiconductor layer 3L and reaches the substrate layer 2L. According to the above configuration, the inner surface 20a of the first portion 21 of the device dividing groove 20 is inclined with respect to the Z-axis direction, and thus, it is possible to easily divide the laser bar LB along the device dividing line L2 in the secondary cleavage (fifth step). More specifically, the width of the first portion 21 in the Y-axis direction is formed in a shape expanding toward the opening side of the device dividing groove 20, and thus, it is possible to increase the volume of the device dividing groove 20. As a result, it is possible to easily break the laser bar LB along the device dividing groove 20. On the other hand, in a case where the entire inner surface 20a of the device dividing groove 20 is inclined at a substantially constant inclination angle with respect to the Z-axis direction, it is difficult to accurately align the central position of the bottom portion of the device dividing groove 20 on the device dividing line L2, and there is a concern that device division cannot be accurately performed. Therefore, as described above, the second portion 22 having a gentler inclination with respect to the Z-axis direction than the first portion 21 is provided on the bottom portion side of the device dividing groove 20, and thus, it is possible to accurately align the central position of the bottom portion of the device dividing groove 20 on the device dividing line L2.

Accordingly, according to the above configuration, it is possible to shorten a time required for device division by facilitating device division (secondary cleavage) by the first portion 21, and it is possible to improve the accuracy of device division by accurately controlling a device division position by the second portion 22.

In addition, the inner surface 20a of the first portion 21 of the device dividing groove 20 constitutes the side surface of the mesa light emitting portion of each of the plurality of device portions C, and the first portion 21 penetrates the semiconductor layer 3L and reaches the substrate layer 2L. According to the above configuration, since the side surface of the mesa light emitting portion is formed as an inclined surface inclined with respect to the Z-axis direction, it is possible to suitably suppress oscillation of the mesa light emitting portion in the lateral direction (oscillation in the Y-axis direction).

In addition, the bottom portion of the device dividing groove 20 has the bottom surface 23 extending in the Y-axis direction. According to the above configuration, it is possible to increase the mechanical strength of the wafer 100 as compared with a case where the device dividing groove 20 is formed in the V shape. As a result, in a case where the back surface processing or the like is performed on the wafer 100 after the device dividing grooves 20 are formed, it is possible to suppress the damage of the wafer 100 and to improve a yield. In addition, since the accuracy of etching deteriorates as the inclination increases, in a case where the device dividing groove 20 is formed in the V shape (that is, in a case where the entire inner surface 20a of the device dividing groove 20 is formed as the inclined surface), it is difficult to control the shape of the device dividing groove 20 formed by etching, and as a result, there is a concern that a dividing direction (a direction along a division surface) at the time of device division becomes unstable (that is, the division surface is not parallel to the Z-axis direction). On the other hand, etching is performed such that the device dividing groove 20 has the bottom surface 23, and thus, the shape of the device dividing groove 20 can be more accurately controlled than in a case where the device dividing groove 20 is formed in the V shape. As a result, the accuracy of device division can be improved.

In addition, the width of the bottom surface 23 of the device dividing groove 20 in the Y-axis direction is 10 μm or less. According to the above configuration, the width of the bottom surface 23 is suppressed to a certain value or less (10 μm or less), and thus, it is possible to easily divide the device along the device dividing groove 20 while obtaining the effect of a case where the device dividing groove 20 has the bottom surface 23 as described above. That is, from the viewpoint of securing the mechanical strength of the wafer 100, the width of the bottom surface 23 may be large. However, when the width of the bottom surface 23 is too large, the laser bar LB is hardly broken along the device dividing groove 20 at the time of device division. According to the above configuration, it is possible to suppress such a disadvantage.

In addition, the inner surface 20b of the device dividing groove 20 in the X-axis direction is inclined with respect to the Y-axis direction such that the inner surface 20b becomes narrower toward the substantially central portion of the device dividing groove 20 in the Y-axis direction toward the outside in the X-axis direction. According to the above configuration, as compared with a case where the shape of the device dividing groove 20 viewed from the Z-axis direction is a simple rectangular shape, it is possible to easily divide the device along the substantially central portion of the device dividing groove 20 in the Y-axis direction.

In addition, as illustrated in FIG. 11, the method for manufacturing the semiconductor laser device 1A includes a step of forming the insulating film 4 after the second step and before the third step, and forming the electrode 5 that is in contact with the top surface 3La of the semiconductor layer 3L via the opening portion 4a of the insulating film 4 and covers at least a part of the portion of the insulating film 4 covering the top surface 3La. According to the above configuration, in a case where the portion of the inner surface 20a of the device dividing groove 20 formed by the semiconductor layer 3L functions as the side surface of the mesa light emitting portion of the semiconductor laser device 1A obtained after device division, since the side surface of the mesa light emitting portion can be appropriately protected by the insulating film 4, it is possible to suppress the occurrence of dark line defects due to the damage to the side surface of the mesa light emitting portion. In addition, the electrode 5 is formed on the top surface 3La of the semiconductor layer 3L via the insulating film 4, and thus, it is possible to further improve the adhesion of the electrode 5. As a result, it is possible to improve the manufacturing quality of the semiconductor laser device 1A.

In addition, since the above-described semiconductor laser device 1A has a configuration that can be easily and accurately manufactured by the above-described manufacturing method, it is possible to improve the yield. Further, in a case where the side surface 3b of the semiconductor stacked body 3 functions as the side surface of the mesa light emitting portion, since the side surface 3c is formed as the inclined surface inclined with respect to the Z-axis direction, it is possible to suitably suppress the oscillation of the mesa light emitting portion in the lateral direction (oscillation in the Y-axis direction).

### MODIFICATION EXAMPLES

### (Modification Example of Device Dividing Groove)

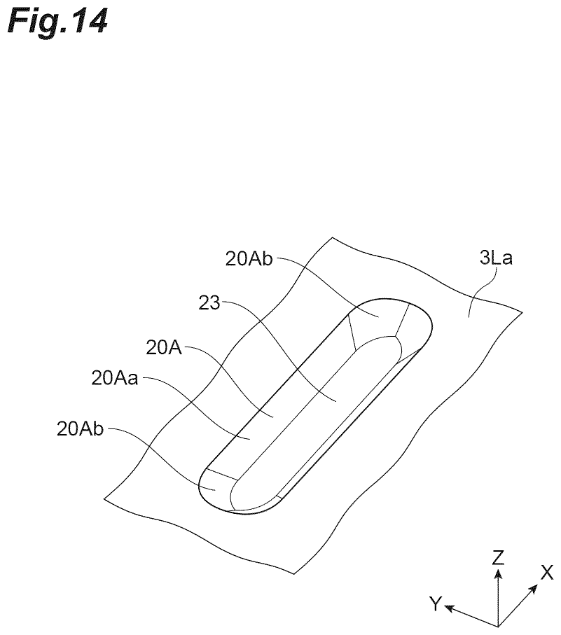

The shape of the device dividing groove formed in the second step is not limited to the shape of the device dividing groove 20 described above. For example, the device dividing groove formed in the second step may be formed in a simple rectangular parallelepiped shape (rectangular shape as viewed from the Z-axis direction). In addition, a device dividing groove 20A according to a modification example illustrated in FIG. 14 may be formed instead of the device dividing groove 20 described above. An inner surface 20Aa of the device dividing groove 20A in the Y-axis direction does not have a portion corresponding to the second portion 22 of the device dividing groove 20, but has only a portion corresponding to the first portion 21 of the device dividing groove 20. That is, the entire inner surface 20Aa of the device dividing groove 20A is inclined with respect to the Z-axis direction. On the other hand, similarly to the inner surface 20b of the device dividing groove 20, an inner surface 20Ab of the device dividing groove 20A in the X-axis direction is inclined with respect to the Y-axis direction to become narrower toward a substantially central portion of the device dividing groove 20A in the Y-axis direction toward an outside in the X-axis direction. In addition, in the device dividing groove 20A, the inner surface 20Ab has an R shape (that is, a shape convex and rounded outward) as viewed from the Z-axis direction. According to the above configuration, it is possible to obtain an effect (that is, an effect capable of easily dividing the device along substantially the center portion of the device dividing groove 20 in the Y-axis direction) similar to the inner surface 20b of the device dividing groove 20. In addition, the inner surface 20Ab is formed in the R shape, and thus, it is possible to reduce a risk of occurrence of cracks in the inner surface 20Ab as compared with a case where the inner surface 20Ab is formed in an angular shape.

### First Modification Example of Semiconductor Laser Device

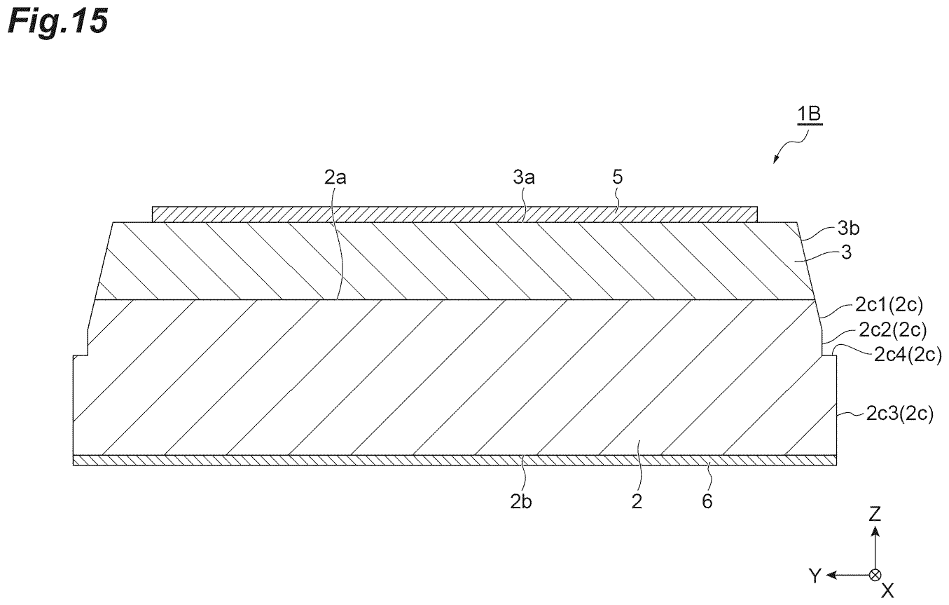

FIG. 15 is a cross-sectional view of a semiconductor laser device 1B according to a first modification example. As illustrated in FIG. 15, the semiconductor laser device 1B is different from the semiconductor laser device 1A in that the insulating film 4 is not provided. The semiconductor laser device 1B can be manufactured by modifying a part of the method for manufacturing the semiconductor laser device 1A described above. For example, the semiconductor laser device 1B can be obtained by omitting the processing of forming the insulating film 4 in the front surface processing step of the method of manufacturing the semiconductor laser device 1A described above. In addition, in a case where the semiconductor laser device 1B is manufactured, it is not necessary to form the insulating film 4 after forming the device dividing groove 20. That is, in a case where the semiconductor laser device 1B is manufactured, the front surface processing step (formation processing of the electrode 5) may be performed before the second step.

### Second Modification Example of Semiconductor Laser Device

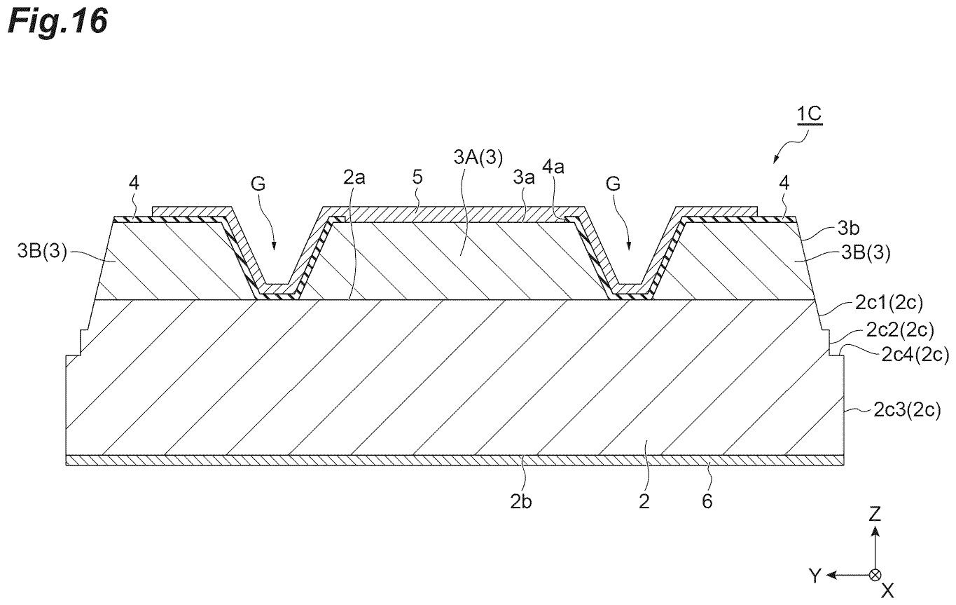

FIG. 16 is a cross-sectional view of a semiconductor laser device 1C according to a second modification example. As illustrated in FIG. 16, the semiconductor laser device 1C is different from the semiconductor laser device 1A in that a pair of semiconductor stacked bodies 3B that do not function as a mesa light emitting portion are provided on both sides of a semiconductor stacked body 3A that functions as a mesa light emitting portion in the Y-axis direction with a groove G interposed therebetween. In the semiconductor laser device 1C, the insulating film 4 is provided on front surfaces of the semiconductor stacked body 3A and the pair of semiconductor stacked bodies 3B, and the insulating film 4 is provided with an opening portion 4a that exposes the top surface 3a of the semiconductor stacked body 3A. In addition, the electrode 5 is provided from an upper portion of one semiconductor stacked body 3B to an upper portion of the other semiconductor stacked body 3B via the semiconductor stacked body 3A. In the semiconductor laser device 1C, an outer side surface 3b of each of the pair of semiconductor stacked bodies 3B in the Y-axis direction and the first portion 2cl and the second portion 2c2 of the side surface 2c of the semiconductor substrate 2 correspond to the inner surface 20a of the device dividing groove 20 formed in the second step. The semiconductor laser device 1C can be manufactured by modifying a part of the method for manufacturing the semiconductor laser device 1A described above. For example, the front surface processing step may be performed before the second step. Here, the front surface processing step includes mesa forming processing of forming the mesa light emitting portion (semiconductor stacked body 3A) by forming the groove G in the semiconductor layer 3L, and processing of forming the insulating film 4 and the electrode 5. The semiconductor laser device 1C can be obtained by performing the second step, the back surface processing step, the third step, the fourth step, and the fifth step similar to the steps in the method for manufacturing the semiconductor laser device 1A after performing such a front surface processing step. According to the semiconductor laser device 1C, it is possible to suppress the occurrence of the above-described dark line defects by covering the side surface of the semiconductor stacked body 3A that functions as the mesa light emitting portion with the insulating film 4 while the front surface processing step can be performed before the second step.

### Other Modification Examples

Although the above embodiment and some modification examples of the present disclosure have been described above, the present disclosure is not limited to the configurations described in the above embodiment and modification examples. The material and shape of each configuration are not limited to the above-described material and shape, and various materials and shapes other than the above-described material and shape can be employed. In addition, some configurations included in the above embodiment and modification examples may be appropriately omitted or changed, or may be arbitrarily combined.

For example, in the above embodiment, in the fourth step (primary cleavage step), the processing of cutting out the square plate-shaped member including only the region A from the disk-shaped wafer 100 is first performed, but such processing may be omitted. That is, the wafer 100 may be directly cleaved along each of the plurality of cleavage lines L1. In this case, the cleavage introducing groove 30 formed on each cleavage line L1 may be provided at an end portion of the wafer 100 in the Y-axis direction.

In addition, after the fourth step (primary cleavage step), a pair of end surfaces of the laser bar LB in the X-axis direction may be coated. For example, an antireflection film (low reflection film) may be provided on an end surface functioning as an emission end surface of the laser beam L among the pair of end surfaces of the laser bar LB in the X-axis direction. On the other hand, a highly reflective film may be provided on an end surface opposite to the end surface functioning as the emission end surface of the laser beam L among the pair of end surfaces of the laser bar LB in the X-axis direction.

In addition, the effect of the first portion 21 and the second portion 22 of the device dividing groove 20 described above (that is, the effect capable of shortening the time required for device division by facilitating device division (secondary cleavage) by the first portion 21 and improving the accuracy of device division by accurately controlling the device division position by the second portion 22) can also be obtained in a case where the device dividing groove forming step (second step) is performed on the laser bar LB (semiconductor member) obtained after the primary cleavage step (fourth step).

In addition, in the above embodiment, both the device dividing groove 20 and the cleavage introducing groove 30 are formed in the first primary surface 100a, but may be formed in the second primary surface 100b. In addition, a primary surface on which the device dividing groove 20 is formed and a primary surface on which the cleavage introducing groove 30 is formed may be different from each other.

In addition, in the above embodiment, although the form in which the inclination angle of the inner surface 20a of the second portion 22 with respect to the Z-axis direction is approximately 0 degrees (that is, the form in which the inner surface 20a of the second portion 22 is substantially parallel to the Z-axis direction) has been exemplified, the inner surface 20a of the second portion 22 may be inclined with respect to the Z-axis direction within a range where the inclination angle is smaller than the inclination angle θ1 of the inner surface 20a of the first portion 21.

In addition, in the above embodiment, although the cleavage introducing groove 30 is formed only outside the device region A1, a part of the cleavage introducing groove 30 may be included inside the device region A1. In this case, for example, the length of the portion of the cleavage introducing groove 30 included outside the device region A1 in the Y-axis direction may be longer than the length of the portion of the cleavage introducing groove 30 included inside the device region A1 in the Y-axis direction. Even in such a configuration, since most of the cleavage introducing groove 30 is formed outside the device region A1, the portion of the cleavage introducing groove 30 formed inside the device region A1 is smaller than the portion of the cleavage introducing groove 30 formed outside the device region A1. As a result, it is possible to suppress the occurrence of the crack caused by the cleavage introducing groove 30 in the laser bar LB obtained by the primary cleavage (fourth step).

In addition, the method for manufacturing a semiconductor laser device of the present disclosure may be applied to a method for manufacturing a super luminescent diode (SLD). That is, a process similar to the step of the present disclosure may be performed on a wafer used for manufacturing the SLD. As a result, effects similar to the method for manufacturing a semiconductor laser device of the present disclosure are obtained. For example, it is possible to suppress residual lateral cracks in the obtained SLD.

What is claimed is:

1. A method for manufacturing a semiconductor laser device that includes a semiconductor substrate and a semiconductor stacked body including an active layer and stacked on the semiconductor substrate, the method comprising:
a first step of preparing a semiconductor member that includes a plurality of device portions to each become the semiconductor laser device, and includes a substrate layer including the semiconductor substrate of each of the plurality of device portions and a semiconductor layer including the semiconductor stacked body of each of the plurality of device portions, in the semiconductor member, the plurality of device portions being arrayed at least in a second direction perpendicular to a first direction parallel to an optical waveguide direction of the semiconductor stacked body as viewed from a thickness direction of the semiconductor member; and
a second step of forming a device dividing groove by etching on a first primary surface on a side of the semiconductor member on which the semiconductor layer is positioned with respect to the substrate layer along a device dividing line extending in the first direction to partition the plurality of device portions arrayed in the second direction, wherein
the device dividing groove has a first portion positioned on an opening side of the device dividing groove and a second portion positioned on a bottom portion side of the device dividing groove with respect to the first portion,
at least a portion of a first inner surface of the device dividing groove formed by the first portion in the second direction is inclined with the thickness direction such that a width of the device dividing groove in the second direction decreases from the first primary surface side toward the second primary surface side opposite to the first primary surface in the semiconductor member, and
an inclination angle of the first inner surface of the first portion with respect to the thickness direction is larger than an inclination angle of the first inner surface of the second portion with respect to the thickness direction.

2. The method for manufacturing a semiconductor laser device according to claim 1, wherein
the device dividing groove penetrates the semiconductor layer, and reaches the substrate layer.

3. The method for manufacturing a semiconductor laser device according to claim 2, wherein
an inner surface of the first portion of the device dividing groove constitutes a side surface of a mesa light emitting portion of each of the plurality of device portions, and
the first portion penetrates the semiconductor layer, and reaches the substrate layer.

4. The method for manufacturing a semiconductor laser device according to claim 1, wherein
a bottom portion of the device dividing groove has a bottom surface extending in the second direction.

5. The method for manufacturing a semiconductor laser device according to claim 4, wherein
a width of the bottom surface of the device dividing groove in the second direction is 20 μm or less.

6. The method for manufacturing a semiconductor laser device according to claim 1, wherein
the etching is dry etching using a chlorine-based gas.

7. The method for manufacturing a semiconductor laser device according to claim 1, wherein
a second inner surface of the device dividing groove in the first direction is inclined with respect to the second direction to become narrow toward a substantially central portion of the device dividing groove in the second direction toward an outside in the first direction.

8. The method for manufacturing a semiconductor laser device according to claim 7, wherein
the second inner surface of the device dividing groove is formed in an R shape as viewed from the thickness direction.

9. The method for manufacturing a semiconductor laser device according to claim 1, wherein
an extending direction of the device dividing line is parallel to a [01-1] direction of the substrate layer.

10. The method for manufacturing a semiconductor laser device according to claim 1, wherein
the plurality of device portions are arrayed in a matrix in the first direction and the second direction, and
the method further includes:
a third step of forming a cleavage introducing groove to become a starting point of a cleavage on the first primary surface at a position overlapping a cleavage line extending in the second direction to partition the plurality of device portions arrayed in the first direction after the second step;
a fourth step of obtaining a plurality of laser bars including a plurality of device portions arrayed one-dimensionally in the second direction by cleaving the semiconductor member along the cleavage line; and
a fifth step of cleaving each of the plurality of laser bars along the device dividing line.

11. The method for manufacturing a semiconductor laser device according to claim 1, wherein
the second step includes a step of forming a resist film in which an opening portion overlapping a region including a central portion of a predetermined region where the device dividing groove is formed is provided on the first primary surface of the semiconductor member before the etching, and
a thickness of the resist film at a peripheral edge portion of the opening portion is formed to be thinned toward an end portion of the opening portion along the second direction.

12. The method for manufacturing a semiconductor laser device according to claim 10, further comprising:
a step of forming an insulating film provided to cover a top surface of the semiconductor layer of the semiconductor member and an inner surface of the device dividing groove, an opening portion in which a part of a top surface is exposed being provided in the insulating film, and forming an electrode covering at least a part of a portion of the insulating film that is in contact with the top surface via the opening portion and covers the top surface, after the second step and before the third step.

13. A semiconductor laser device comprising:
a semiconductor substrate; and
a semiconductor stacked body including an active layer and stacked on the semiconductor substrate, wherein
a first side surface of the semiconductor stacked body in a second direction perpendicular to a first direction parallel to an optical waveguide direction of the semiconductor stacked body as viewed from a thickness direction of the semiconductor substrate is continuously provided with a second side surface of the semiconductor substrate in the second direction,
the first side surface is inclined with the thickness direction from the semiconductor stacked body side toward the semiconductor substrate side along the thickness direction toward an outside in the second direction,
the second side surface includes:
a first portion connected to the first side surface, continuous with the first side surface, and is inclined with respect to the thickness direction; and
a second portion connected to the first portion opposite to a side on which the first side surface is positioned with respect to the first portion, and
an inclination angle of the first portion with respect to the thickness direction is larger than an inclination angle of the second portion with respect to the thickness direction.
